(19) United States
(12) Patent Application Publication
(10) Pub. No.: US 2026/0147273 A1
(43) Pub. Date: May 28, 2026

(54) SEMICONDUCTOR PHOTORESIST COMPOSITION AND METHOD OF FORMING PATTERNS USING THE COMPOSITION

(71) Applicant: SAMSUNG SDI CO., LTD., Yongin-si (KR)

(72) Inventors: Chaeeun LEE, Suwon-si (KR); Miyeon HAN, Suwon-si (KR); Joonhee HAN, Suwon-si (KR); Yunju CHAE, Suwon-si (KR); Hyun LEE, Suwon-si (KR); Jimin KIM, Suwon-si (KR); Soobin LIM, Suwon-si (KR)

(21) Appl. No.: 19/393,081

(22) Filed: Nov. 18, 2025

(30) Foreign Application Priority Data
Nov. 28, 2024 (KR) 10-2024-0174121

(51) Int. Cl. G03F 7/004; H01L 21/027; H01L 21/311

(52) U.S. Cl. CPC G03F 7/0042; G03F 7/0045; H10P 50/73; H10P 76/2042

(57) ABSTRACT

A semiconductor photoresist composition and a method of forming patterns using the semiconductor photoresist composition are provided. The semiconductor photoresist composition includes an organometallic compound; an alcohol compound substituted with at least one halogen; a halogen-unsubstituted alcohol compound; and a solvent.

### CROSS-REFERENCE TO RELATED APPLICATION

This application claims priority to and the benefit of Korean Patent Application No. 10-2024-0174121, filed on Nov. 28, 2024, in the Korean Intellectual Property Office, the entire content of which is incorporated herein by reference.

### BACKGROUND

### 1. Field

This disclosure relates to a semiconductor photoresist composition and a method of forming patterns using the same.

### 2. Description of the Related Art

Extreme ultraviolet (EUV) lithography has drawn much attention as an essential technology for manufacturing next generation semiconductor devices (e.g., semiconductor chips). The EUV lithography is a pattern-forming technology using an EUV ray having a wavelength of 13.5 nm as an exposure light source. It is known that extremely fine patterns (e.g., less than or equal to 20 nm) may be formed during the exposure process in the manufacture of semiconductor devices (e.g., semiconductor chips).

The realization of EUV lithography depends on the development of compatible photoresists capable of achieving a spatial resolution of less than or equal to 16 nm. Currently, efforts are being made to address the insufficient specifications of chemically amplified (CA) photoresists, such as resolution, photospeed, and feature roughness (also referred to as a line edge roughness or LER) for next generation devices.

Intrinsic image blurring due to an acid catalyzed reaction in these polymer-type (kind) photoresists limits a resolution in small feature sizes, a challenge that has persisted in electron beam (e-beam) lithography for a long time. Chemically amplified (CA) photoresists are designed for high sensitivity, but their typical elemental makeup reduces light absorbance of the photoresists at a wavelength of 13.5 nm, thus decreasing their sensitivity. Consequently, the chemically amplified (CA) photoresists may face more difficulties under an EUV exposure.

Additionally, CA photoresists may have difficulties with the small feature sizes due to roughness issues. Experimentally, line edge roughness (LER) of the CA photoresists increases as photospeed decreases, partially due to the nature of acid catalyst processes. Therefore, a novel high-performance photoresist is desired or needed in the semiconductor industry to address these defects and problems with CA photoresists.

To overcome the aforementioned drawbacks of the chemically amplified (CA) organic photosensitive compositions, inorganic photosensitive compositions have been researched. Inorganic photosensitive compositions are primarily or mainly used for negative tone patterning and exhibit resistance to removal by developer compositions due to chemical modification through a non-chemical amplification mechanism. Inorganic compositions contain an inorganic element with a higher EUV absorption rate than hydrocarbons, thus securing sensitivity through the nonchemical amplification mechanism. Additionally, they are less sensitive to stochastic effects and are known to have low line edge roughness and fewer defects.

Inorganic photoresists based on peroxopolyacids of tungsten mixed with tungsten, niobium, titanium, and/or tantalum have been reported as radiation sensitive materials for patterning.

These materials are effective for patterning large pitches for bilayer configuration as far ultraviolet (deep UV), X-ray, and electron beam sources. When cationic hafnium metal oxide sulfate (HfSOx) materials, along with a peroxo complexing agent, were used to image a 15 nm half-pitch (HP) through projection EUV exposure, improved performance was observed. This system exhibits a high performance of a non-CA photoresist and has a practicable photospeed near to a requirement for an EUV photoresist. However, the hafnium metal oxide sulfate material having the peroxo complexing agent has some practical drawbacks. First, these materials are coated in a mixture of corrosive sulfuric acid/hydrogen peroxide and have insufficient shelf-life stability. Second, structural changes for performance improvement as a composite mixture are challenging. Third, development should be performed in a TMAH (tetramethylammonium hydroxide) solution at an extremely high concentration of 25 wt % and/or the like (e.g., at an extremely high concentration of 25 wt % or higher).

To address these issues, research has focused on developing molecules that include tin, which have excellent or suitable absorption of extreme ultraviolet rays. For an organotin polymer among these tin-containing molecules (e.g., molecules including tin), alkyl ligands are dissociated by light absorption or secondary electrons produced thereby. The dissociated alkyl ligands are then crosslinked with adjacent chains through oxo bonds, enabling negative tone patterning that may not be removed by an organic developer. Although this organotin polymer exhibits greatly improved sensitivity and maintains desired resolution and line edge roughness (LER), further improvement in patterning characteristics is needed or desired for commercial viability.

### SUMMARY

One or more aspects of embodiments of the present disclosure are directed toward a semiconductor photoresist composition that has enhanced (e.g., improved or suitable) coating properties and bridge defects while maintaining excellent or suitable sensitivity characteristics.

One or more aspects of embodiments of the present disclosure are directed toward a method of forming patterns using the semiconductor photoresist composition.

Additional aspects will be set forth in part in the description which follows and, in part, will be apparent from the description, or may be learned by practice of the presented embodiments of the disclosure.

A semiconductor photoresist composition according to one or more embodiments includes an organometallic compound, an alcohol compound substituted with at least one halogen, a halogen-unsubstituted alcohol compound, and a solvent.

A method of forming patterns according to one or more embodiments includes forming an etching-objective layer on a substrate, coating the semiconductor photoresist composition on the etching-objective layer to form a photoresist film, patterning the photoresist film to form a photoresist pattern, and etching the etching-objective layer using the photoresist pattern as an etching mask.

The semiconductor photoresist composition according to one or more embodiments may have improved sensitivity and coating properties to improve (e.g., reduce) surface roughness, thereby providing a photoresist pattern having excellent or suitable LER and pattern line width. For instance, the semiconductor photoresist composition may enhance sensitivity and coating properties to reduce surface roughness, resulting in a photoresist pattern with reduced or suitable LER and pattern line width. Additionally, the method of forming patterns using this composition should ensure precise etching and patterning, contributing to the overall efficiency and effectiveness of semiconductor manufacturing processes. These advancements should improve semiconductor device performance and reliability.

### BRIEF DESCRIPTION OF THE DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The preceding and other aspects, features, and advantages of certain embodiments of the disclosure will be more apparent from the following description taken in conjunction with the accompanying drawings, in which:

FIGS. 1A-1E are cross-sectional views for illustrating (explaining) a method of forming patterns using a semiconductor photoresist composition according to one or more embodiments of the present disclosure.

### DETAILED DESCRIPTION

The present disclosure may be modified in many alternate forms, and thus specific embodiments will be exemplified in the drawing and described in more detail. It should be understood, however, that it is not intended to limit the present disclosure to the particular forms disclosed, but rather, is intended to cover all modifications, equivalents, and alternatives falling within the spirit and scope of the present disclosure.

Hereinafter, referring to the drawings, one or more embodiments of the present disclosure will be described in more detail. In the following description of the present disclosure, the well-established functions or constructions will not be described in order to make the present disclosure concise.

To clearly illustrate the present disclosure, certain unessential description and relationships are not provided, and throughout the disclosure, the same or similar configuration elements are designated by the same reference numerals. Also, because the size and thickness of each configuration shown in the drawing are shown for better understanding and ease of description, the present disclosure is not necessarily limited thereto.

In the drawings, the thickness of layers, films, panels, regions, and/or the like, are exaggerated for clarity. In the drawings, the thickness of a part of layers or regions, and/or the like, is exaggerated for convenience of explanation. It will be understood that if (e.g., when) an element such as a layer, film, region, or substrate is referred to as being “on” another element, it can be directly on the other element or intervening elements may also be present.

As used herein, “substituted” refers to replacement of a hydrogen atom by deuterium, a halogen, a hydroxyl group, a carboxyl group, a thiol group, a cyano group, a nitro group, —NRR′ (wherein, R and R′ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, or a combination thereof. “Unsubstituted” refers to non-replacement of a hydrogen atom by another substituent and remaining of the hydrogen atom.

As used herein, if (e.g., when) a definition is not otherwise provided, “alkyl group” refers to a linear or branched aliphatic hydrocarbon group. The alkyl group may be “saturated alkyl group” without any double bond or triple bond.

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if (e.g., when) a definition is not otherwise provided, “cycloalkyl group” refers to a monovalent cyclic aliphatic hydrocarbon group.

The cycloalkyl group may be a C3 to C8 cycloalkyl group, for example, a C3 to C7 cycloalkyl group, a C3 to C6 cycloalkyl group, a C3 to C5 cycloalkyl group, or a C3 to C4 cycloalkyl group. For example, the cycloalkyl group may be a cyclopropyl group, a cyclobutyl group, a cyclopentyl group, or a cyclohexyl group, but the present disclosure is not limited thereto.

As used herein, “aryl group” refers to a substituent in which all atoms in the cyclic substituent have a p-orbital and these p-orbitals are conjugated and may include a monocyclic or fused ring polycyclic functional group (i.e., rings sharing adjacent pairs of carbon atoms).

As used herein, “heteroaryl group” may refer to an aryl group including at least one heteroatom selected from among N, O, S, P, and Si. Two or more heteroaryl groups are linked by a sigma bond directly, or if (e.g., when) the heteroaryl group includes two or more rings, the two or more rings may be fused. When the heteroaryl group is a fused ring, each ring may include one to three heteroatoms.

As used herein, unless otherwise defined, “alkenyl group” refers to an aliphatic unsaturated alkenyl group including at least one double bond as a linear or branched aliphatic hydrocarbon group.

As used herein, unless otherwise defined, “alkynyl group” refers to an aliphatic unsaturated alkynyl group including at least one triple bond as a linear or branched aliphatic hydrocarbon group.

Hereinafter, a semiconductor photoresist composition according to one or more embodiments is described.

In one or more embodiments, a semiconductor photoresist composition according to the present disclosure includes an organometallic compound, a halogenated alcohol compound, a halogen-unsubstituted alcohol compound, and a solvent.

The semiconductor photoresist composition according to the present disclosure is a composition including an organometallic compound, two types (kinds) of alcohol compounds, and a solvent, and e.g., by including the halogenated alcohol compound (e.g., an alcohol compound substituted with at least one halogen) and the halogen-unsubstituted alcohol compound together (e.g., simultaneously), sensitivity to extreme ultraviolet rays may be increased and pattern roughness may be improved in a pattern formed using the composition.

For example, this composition, which incorporates both halogenated and halogen-unsubstituted alcohol compounds, enhances sensitivity to extreme ultraviolet rays and improves pattern roughness in the resulting photoresist pattern.

The alcohol compound substituted with at least one halogen may be represented by Chemical Formula 1.

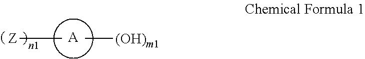

In Chemical Formula 1,
Z may be a halogen,
A may be at least one selected from among a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkane, a substituted or unsubstituted C3 to C20 cycloalkene, and a substituted or unsubstituted C6 to C20 aromatic ring,
n1 and m1 may each independently be an integer of greater than or equal to 1, and
n1+m1 may be an integer less than or equal to a valence of A.

A may have one or more suitable modifications, such as being a divalent group, a trivalent group, or a tetravalent group, depending on the number of linked substituents.

For example, A may be at least one selected from among a substituted or unsubstituted C1 to C5 alkylene group, a substituted or unsubstituted C2 to C5 alkenylene group, a substituted or unsubstituted C2 to C5 alkynylene group, a substituted or unsubstituted C3 to C10 cycloalkane, and a substituted or unsubstituted C6 to C12 aromatic ring.

As an example, A may be at least one selected from among a substituted or unsubstituted C1 to C5 alkylene group, a substituted or unsubstituted C3 to C10 cycloalkane, and a substituted or unsubstituted C6 to C12 aromatic ring.

For example, A may be at least one selected from among a substituted or unsubstituted methylene group, a substituted or unsubstituted ethylene group, a substituted or unsubstituted propylene group, and a substituted or unsubstituted benzene.

For example, Z may be at least one selected from among fluoro, chloro, and iodo.

For example, Z may be at least one selected from among fluoro and iodo.

In one or more embodiments, the alcohol compound (Chemical Formula 1) may be represented by any one of Chemical Formula 1-1 to Chemical Formula 1-4.

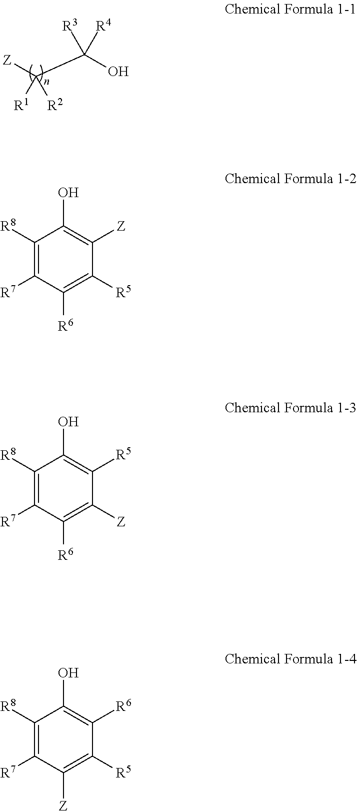

In Chemical Formula 1-1 to Chemical Formula 1-4,
Z may be a halogen,
R¹ to R⁸ may each independently be hydrogen, a halogen, a hydroxyl group, an amino group, a nitro group, a substituted or unsubstituted C1 to C30 amine group, a substituted or unsubstituted C1 to C10 alkyl group, or a substituted or unsubstituted C6 to C20 aryl group, and
n is an (one of) integer(s) from 1 to 10.

In one or more embodiments, R¹ to R⁸ may each independently be hydrogen, a halogen, a hydroxyl group, a substituted or unsubstituted C1 to C10 alkyl group, or a substituted or unsubstituted C6 to C20 aryl group.

In one or more embodiments, R¹ to R⁸ may each independently be hydrogen, a halogen, a hydroxyl group, a substituted or unsubstituted C1 to C5 alkyl group, or a substituted or unsubstituted C6 to C12 aryl group.

For example, R¹ to R⁸ may each independently be hydrogen, a halogen, a hydroxyl group, a substituted or unsubstituted methyl group, a substituted or unsubstituted ethyl group, a substituted or unsubstituted propyl group, a substituted or unsubstituted iso-propyl group, a substituted or unsubstituted butyl group, a substituted or unsubstituted sec-butyl group, a substituted or unsubstituted iso-butyl group, a substituted or unsubstituted tert-butyl group, a substituted or unsubstituted phenyl group, or a combination thereof.

For example, the alcohol compound substituted with at least one halogen may be selected from among the compounds in Group 1.

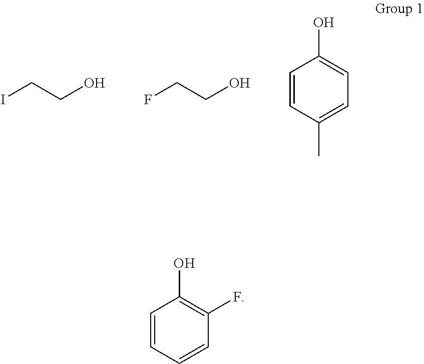

The halogen-unsubstituted alcohol compound may be represented by Chemical Formula 2.

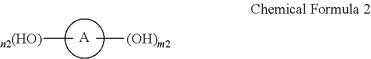

In Chemical Formula 2,
B may be at least one selected from among a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkane, a substituted or unsubstituted C3 to C20 cycloalkene, and a substituted or unsubstituted C6 to C20 aromatic ring,
n2 and m2 may each independently be of greater than or equal to 0,
n2+m2 may be an integer of greater than or equal to 1 and less than or equal to the valence of B, and
substituents in the case of “substituted” may exclude (not include) a halogen.

For example, the sum of n2+m2 may be 1 or 2.

B may have one or more suitable modifications, such as being a divalent group, a trivalent group, or a tetravalent group, depending on the number of linked substituents.

For example, B may be at least one selected from among a substituted or unsubstituted C1 to C5 alkylene group, a substituted or unsubstituted C2 to C5 alkenylene group, a substituted or unsubstituted C2 to C5 alkynylene group, a substituted or unsubstituted C3 to C10 cycloalkane, and a substituted or unsubstituted C6 to C12 aromatic ring.

As an example, B may be at least one selected from among a substituted or unsubstituted C1 to C5 alkylene group, a substituted or unsubstituted C3 to C10 cycloalkane, and a substituted or unsubstituted C6 to C12 aromatic ring.

For example, B may be at least one selected from among a substituted or unsubstituted methylene group, a substituted or unsubstituted ethylene group, a substituted or unsubstituted propylene group, and a substituted or unsubstituted benzene.

In one or more embodiments, the halogen-unsubstituted alcohol compound (Chemical Formula 2) may be represented by Chemical Formula 2-1.

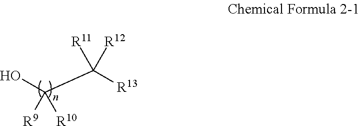

In Chemical Formula 2-1,
R⁹ to R¹³ may each independently be hydrogen, a hydroxyl group, an amino group, a nitro group, a substituted or unsubstituted C1 to C30 amine group, a substituted or unsubstituted C1 to C10 alkyl group, or a substituted or unsubstituted C6 to C20 aryl group, and
n may be one of integers from 1 to 9.

In one or more embodiments, R⁹ to R¹³ may each independently be hydrogen, a hydroxyl group, a substituted or unsubstituted C1 to C10 alkyl group, or a substituted or unsubstituted C6 to C20 aryl group.

In one or more embodiments, R⁹ to R¹³ may each independently be hydrogen, a hydroxyl group, a substituted or unsubstituted C1 to C5 alkyl group, or a substituted or unsubstituted C6 to C12 aryl group.

For example, R⁹ to R¹³ may each independently be hydrogen, a hydroxyl group, a substituted or unsubstituted methyl group, a substituted or unsubstituted ethyl group, a substituted or unsubstituted propyl group, a substituted or unsubstituted iso-propyl group, a substituted or unsubstituted butyl group, a substituted or unsubstituted sec-butyl group, a substituted or unsubstituted iso-butyl group, a substituted or unsubstituted tert-butyl group, a substituted or unsubstituted phenyl group, or a combination thereof.

For example, the halogen-unsubstituted alcohol compound may be one selected from among the compounds in Group 2.

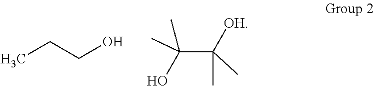

The alcohol compound substituted with at least one halogen and the halogen-unsubstituted alcohol compound may be included in a weight ratio of about 15:1 to about 1:15.

For example, the at least one halogen substituted alcohol compound and the halogen-unsubstituted alcohol compound may be included in a weight ratio of about 10:1 to about 1:15, about 8:1 to about 1:15, or about 5:1 to about 1:13.

In one or more embodiments, each of the alcohol compound substituted with at least one halogen and the halogen-unsubstituted alcohol compound may be included in an amount of about 0.01 wt % to about 20 wt % based on 100 wt % of a total weight of the semiconductor photoresist composition.

For example, each of the alcohol compound substituted with at least one halogen and the halogen-unsubstituted alcohol compound may be included in an amount of about 0.01 wt % to about 10 wt %, about 0.02 wt % to about 10 wt %, about 0.03 wt % to about 10 wt %, or about 0.05 wt % to about 10 wt % based on 100 wt % of a total weight of the semiconductor photoresist composition.

In one or more embodiments, the organometallic compound may be included in an amount of about 0.5 wt % to about 30 wt % based on 100 wt % of a total weight of the semiconductor photoresist composition.

The semiconductor photoresist composition according to one or more embodiments may improve the sensitivity of a photoresist by including the alcohol compound substituted with at least one halogen and/or the halogen-unsubstituted alcohol compound in the preceding amount ranges.

The organometallic compound may be an organotin compound including at least one selected from among (of) an organic oxy group and an organic carbonyloxy group.

The organometallic compound may be represented by Chemical Formula 3.

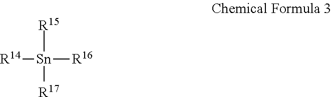

In Chemical Formula 3,
R¹⁴ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R¹⁵ to R¹⁷ may each independently be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, an alkoxy or aryloxy group —OR^{b}, wherein
R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, a carboxyl group —O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, an alkylamido or dialkylamido group —NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, an amidato group —NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, an amidinato group —NR^{h}C(NRⁱ)R^{j}, wherein R^{h}, Rⁱ, and R^{j} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, an alkylthio or arylthio group —SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, or a thiocarboxyl group —S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
1 at least one selected from among (of) R¹⁵ to R¹⁷ may be selected from among the alkoxy or aryloxy group —OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, the carboxyl group —O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, the alkylamido or dialkylamido group —NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, the amidato group —NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, the amidinato group —NR^{h}C(NRⁱ)R^{j}, wherein R^{h}, Rⁱ, and R^{j} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, the alkylthio or arylthio group —SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and the thiocarboxyl group —S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

In one or more embodiments, at least one selected from among (of) R¹⁵ to R¹⁷ may be selected from among the alkoxy or aryloxy group —OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and the carboxyl group —O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

In one or more embodiments, because the compound represented by Chemical Formula 3 includes —OR^{b} or —OC(═O)R^{c} as a ligand, a pattern formed using a semiconductor photoresist composition including the compound may exhibit excellent or suitable limit resolution.

In some embodiments, the ligand of —OR^{b} or —OC(═O)R^{c} may determine the solubility of the compound represented by Chemical Formula 3 in a solvent.

R¹⁴ may be a substituted or unsubstituted C1 to C8 alkyl group, a substituted or unsubstituted C3 to C8 cycloalkyl group, a substituted or unsubstituted C2 to C8 aliphatic unsaturated organic group including one or more double bonds or triple bonds, a substituted or unsubstituted C6 to C20 aryl group, a substituted or unsubstituted C4 to C20 heteroaryl group, a carbonyl group, an ethoxy group, a propoxy group, or a combination thereof,
R^{b} may be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} may be hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.
R¹⁴ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a combination thereof,
R^{b} may be an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof, and
R^{c} may be hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof.

In some embodiments, the organometallic compound may be represented by Chemical Formula 4 or Chemical Formula 5.

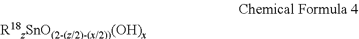

In Chemical Formula 4,
R¹⁸ may be a C1 to C31 hydrocarbyl group, 0<z≤2, and 0<(z+x)≤4;

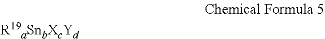

wherein, in Chemical Formula 5,
R¹⁹ may be a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X may be sulfur(S), selenium (Se), or tellurium (Te),
Y may be —OR^{m} or —OC(═O)Rⁿ,
wherein R^{m} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
Rⁿ may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d may each independently be an integer of 1 to 20.

The solvent included in the semiconductor photoresist composition according to one or more embodiments may be an organic solvent, and may be for example aromatic compounds (e.g., xylene, toluene, and/or the like), alcohols (e.g., 4-methyl-2-pentanol, 4-methyl-2-propanol, 1-butanol, methanol, isopropyl alcohol, 1-propanol), ethers (e.g., anisole, tetrahydrofuran), esters (n-butyl acetate, propylene glycol monomethyl ether acetate, ethyl acetate, ethyl lactate), ketones (e.g., methyl ethyl ketone, 2-heptanone), or a mixture thereof, but the present disclosure is not limited thereto.

The semiconductor photoresist composition according to one or more embodiments may further include a resin, e.g., in addition to the aforementioned organometallic compound, alcohol compound substituted with at least one halogen, halogen-unsubstituted alcohol compound, and solvent.

The resin may be a phenol-based resin including at least one aromatic moieties in Group 3.

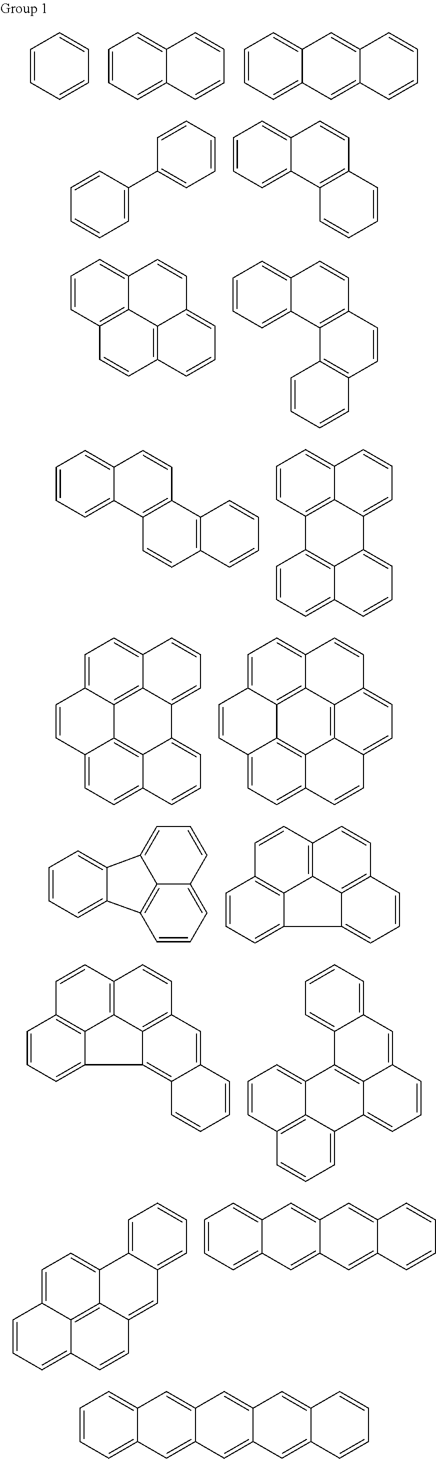

The resin may have a weight average molecular weight of about 500 to about 20,000.

The resin may be included in an amount of about 0.1 wt % to about 50 wt % based on 100 wt % of a total amount (weight) of the semiconductor photoresist composition.

If (e.g., when) the resin is included in the preceding amount range, the semiconductor photoresist composition may have excellent or suitable etch resistance and heat resistance.

In one or more embodiments, the semiconductor photoresist composition may be composed of the aforementioned organometallic compound, alcohol compound substituted with at least one halogen, halogen-unsubstituted alcohol compound, solvent, and resin.

The semiconductor photoresist composition according to the aforementioned embodiments may further include one or more additives as needed. Examples of the additives may be a surfactant, a crosslinking agent, a leveling agent, an organic acid, a quencher, or a combination thereof.

The surfactant may include for example an alkyl benzene sulfonate salt, an alkyl pyridinium salt, polyethylene glycol, a quaternary ammonium salt, or a combination thereof, but the present disclosure is not limited thereto.

The crosslinking agent may be for example a melamine-based crosslinking agent, a substituted urea-based crosslinking agent, an acryl-based crosslinking agent, an epoxy-based crosslinking agent, or a polymer-based crosslinking agent, but the present disclosure is not limited thereto. It may be a crosslinking agent having at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be used for improving coating flatness during printing and may be a commercially available leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but the present disclosure is not limited thereto.

The quencher may be diphenyl (p-tolyl) amine, methyl diphenyl amine, triphenyl amine, phenylenediamine, naphthylamine, diaminonaphthalene, or a combination thereof.

Each use amount of the additives may be controlled or selected depending on desired or suitable properties.

In some embodiments, the semiconductor photoresist composition may further include a silane coupling agent as an adherence enhancer in order to improve a close-contacting force with the substrate (e.g., in order to improve adherence of the semiconductor photoresist composition to the substrate). The silane coupling agent may be for example a silane compound including a carbon-carbon unsaturated bond such as vinyltrimethoxysilane, vinyl triethoxysilane, vinyl trichlorosilane, vinyl tris(β-methoxyethoxy) silane; or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy [3-(phenylamino) propyl]silane, and/or the like, but the present disclosure is not limited thereto.

The semiconductor photoresist composition may be formed into a pattern having a high aspect ratio without a collapse. Accordingly, in order to form a fine pattern having a width of, for example, about 5 nanometer (nm) to about 100 nm, for example, about 5 nm to about 80 nm, for example, about 5 nm to about 70 nm, for example, about 5 nm to about 50 nm, for example, about 5 nm to about 40 nm, for example, about 5 nm to about 30 nm, or for example, about 5 nm to about 20 nm, the semiconductor photoresist composition may be used for a photoresist process using light in a wavelength in a range of about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to one or more embodiments may be used to realize extreme ultraviolet lithography using an EUV light source of a wavelength of about 13.5 nm.

According to one or more embodiments, a method of forming patterns using the aforementioned semiconductor photoresist composition is provided. For example, the manufactured pattern may be a photoresist pattern.

The method of forming patterns according to one or more embodiments includes forming an etching-objective layer on a substrate, coating the semiconductor photoresist composition on the etching-objective layer to form a photoresist film, patterning the photoresist film to form a photoresist pattern, and etching the etching-objective layer using the photoresist pattern as an etching mask.

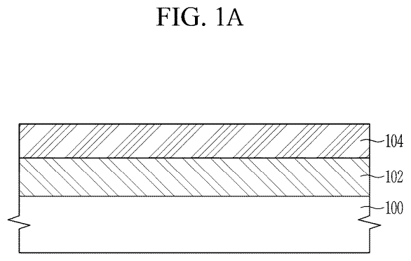

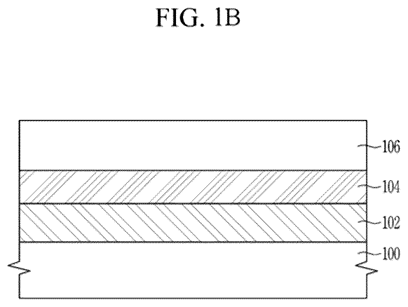

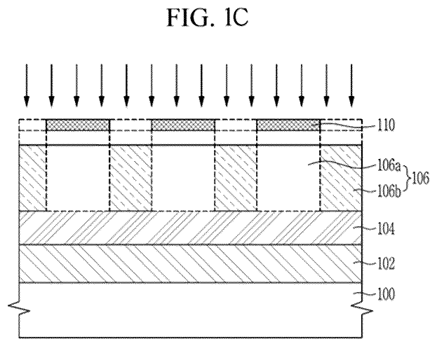

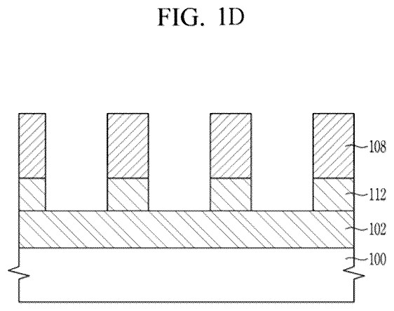

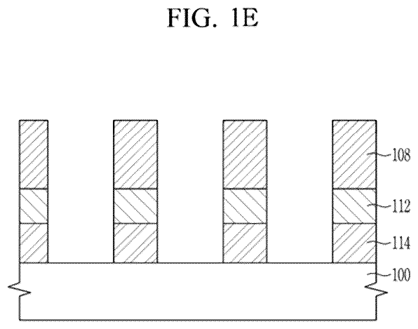

Hereinafter, a method of forming patterns using the semiconductor photoresist composition is described referring to FIGS. 1A-1E. FIGS. 1A-1E are cross-sectional views for illustrating (explaining) a method of forming patterns using a semiconductor photoresist composition according to one or more embodiments.

Referring to FIG. 1A, an object for etching (e.g., etching-objective layer or etching-target layer) is prepared. The object for etching may be a thin film 102 formed on a semiconductor substrate 100. Hereinafter, the object for etching is limited to the thin film 102. A surface of the thin film 102 is washed to remove impurities and/or the like remaining thereon. The thin film 102 may be for example a silicon nitride layer, a polysilicon layer, or a silicon oxide layer.

Subsequently, a resist underlayer composition for forming a resist underlayer 104 is spin-coated on the surface of the washed thin film 102. However, the embodiments are not limited thereto, and one or more suitable coating methods, for example a spray coating, a dip coating, a knife edge coating, a printing method, for example an inkjet printing and a screen printing, and/or the like may be used.

The coating process of the resist underlayer may not be provided, and hereinafter, a process including a coating of the resist underlayer is described.

Then, the coated resist underlayer composition is dried and baked to form a resist underlayer 104 on the thin film 102. The baking may be performed at about 100° C. to about 500° C., for example, about 100° C. to about 300° C.

The resist underlayer 104 is formed between the substrate 100 and a photoresist film 106 and thus may prevent or reduce non-uniformity of pattern formability of a photoresist line width if (e.g., when) a ray reflected from on the interface between the substrate 100 and the photoresist film 106 or a hardmask between layers is scattered into an unintended photoresist region.

Referring to FIG. 1B, the photoresist film 106 is formed by coating the semiconductor photoresist composition on the resist underlayer 104. The photoresist film 106 is obtained by coating the aforementioned semiconductor photoresist composition on the thin film 102 formed on the substrate 100 and then, curing it through a heat treatment.

For example, the formation of a pattern by using the semiconductor photoresist composition may include coating the semiconductor photoresist composition on the substrate 100 having the thin film 102 through spin coating, slit coating, inkjet printing, and/or the like and then, drying it to form the photoresist film 106.

The semiconductor photoresist composition has already been described and illustrated in detail and will not be illustrated again.

Subsequently, a substrate 100 having the photoresist film 106 is subjected to a first baking process. The first baking process may be performed at about 80° C. to about 120° C.

Referring to FIG. 1C, the photoresist film 106 may be selectively exposed using a patterned mask 110.

For example, the exposure may use an activation radiation with light having a high energy wavelength light such as EUV (extreme ultraviolet; a wavelength of about 13.5 nm), an E-Beam (an electron beam), and/or the like as well as light with shorter wavelengths such as an i-line (a wavelength of about 365 nm), a KrF excimer laser (a wavelength of about 248 nm), an ArF excimer laser (a wavelength of about 193 nm), and/or the like.

For example, light or the exposure beam for the exposure according to one or more embodiments may be short-wavelength light having a wavelength in a range of about 5 nm to about 150 nm and/or a high energy wavelength, for example, EUV (extreme ultraviolet; a wavelength of 13.5 nm), and/or may be an E-Beam (an electron beam), and/or the like.

The exposed region 106b of the photoresist film 106 has a different solubility from the unexposed region 106a of the photoresist film 106 by forming a polymer by a crosslinking reaction such as condensation between organometallic compounds.

Subsequently, the substrate 100 is subjected to a second baking process. The second baking process may be performed at a temperature of about 90° C. to about 200° C. The exposed region 106b of the photoresist film 106 becomes easily indissoluble regarding a developer due to the second baking process.

In FIG. 1D, the unexposed region 106a of the photoresist film is dissolved and removed using the developer to form a photoresist pattern 108. For example, the unexposed region 106a of the photoresist film is dissolved and removed by using an organic solvent such as 2-heptanone and/or the like to complete the photoresist pattern 108 corresponding to the negative tone image.

As described herein, a developer used in a method of forming patterns according to one or more embodiments may be an organic solvent. The organic solvent used in the method of forming patterns according to one or more embodiments may be for example ketones such as methylethylketone, acetone, cyclohexanone, 2-heptanone, and/or the like, alcohols such as 4-methyl-2-propanol, 1-butanol, isopropanol, 1-propanol, methanol, and/or the like, esters such as propylene glycol monomethyl ether acetate, ethyl acetate, ethyl lactate, n-butyl acetate, butyrolactone, and/or the like, aromatic compounds such as benzene, xylene, toluene, and/or the like, or a combination thereof.

However, the photoresist pattern according to one or more embodiments is not necessarily limited to the negative tone image but may be formed to have a positive tone image. Here, a developer used for forming the positive tone image may be a quaternary ammonium hydroxide composition such as tetraethylammonium hydroxide, tetrapropylammonium hydroxide, tetrabutylammonium hydroxide, or a (e.g., any suitable) combination thereof.

As described herein, exposure to light having a high energy such as EUV (extreme ultraViolet; a wavelength of 13.5 nm), an E-Beam (an electron beam), and/or the like as well as light having a shorter wavelength such as i-line (wavelength of about 365 nm), KrF excimer laser (wavelength of about 248 nm), ArF excimer laser (wavelength of about 193 nm), and/or the like may provide a photoresist pattern 108 having a width of about 5 nm to about 100 nm. For example, the photoresist pattern 108 may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In one or more embodiments, the photoresist pattern 108 may have a pitch (center-to-center distance between adjacent features in the pattern) having (with) a half-pitch of less than or equal to about 50 nm, for example less than or equal to about 40 nm, for example less than or equal to about 30 nm, for example less than or equal to about 20 nm, or for example less than or equal to about 15 nm, and a line width roughness of less than or equal to about 10 nm, less than or equal to about 5 nm, less than or equal to about 3 nm, or less than or equal to about 2 nm.

Subsequently, the photoresist pattern 108 is used as an etching mask to etch the resist underlayer 104. Through this etching process, an organic film pattern 112 is formed. The organic film pattern 112 also may have a width corresponding to that of the photoresist pattern 108.

Referring to FIG. 1E, the exposed thin film 102 is etched by applying the photoresist pattern 108 as an etching mask. As a result, the thin film is formed as a thin film pattern 114.

In the exposure process, the thin film pattern 114 formed by using the photoresist pattern 108 formed through the exposure process performed by using an EUV light source may have a width corresponding to that of the photoresist pattern 108. For example, the thin film pattern 114 may have a width (e.g., line width) of about 5 nm to about 100 nm which is equal to that of the photoresist pattern 108. For example, the thin film pattern 114 formed by using the photoresist pattern 108 formed through the exposure process performed by using an EUV light source may have a width (e.g., line width) of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or a width (e.g., line width) of less than or equal to about 20 nm, like that of the photoresist pattern 108.

Hereinafter, the present disclosure will be described in more detail through examples of the preparation of the aforementioned semiconductor photoresist composition. However, the present disclosure is technically not restricted by the following examples.

### EXAMPLES

### Synthesis of Organometallic Compounds

### Synthesis Example 1

40.7 g of t-butylSnPhs and 300 g of propionic acid were added to a 250 mL two-necked round-bottom flask and heated under reflux for 24 hours.

Unreacted propionic acid was removed under reduced pressure to obtain a compound represented by Chemical Formula 5.

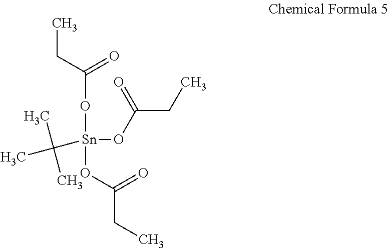 [SMILES: CCC(=O)[O][Sn]([O]C(=O)CC)([O]C(=O)CC)[C](C)(C)C]

### Synthesis Example 2

30 mL of anhydrous pentane was added to 10 g of t-AmylSnCl₃, the temperature was maintained at 0° C., and then 7.4 g of diethylamine and 6.1 g of ethanol were added thereto, and stirred at room temperature for 1 hour. When the reaction was completed, the resultant was filtered, concentrated and vacuum-dried to obtain a compound represented by Chemical Formula 6.

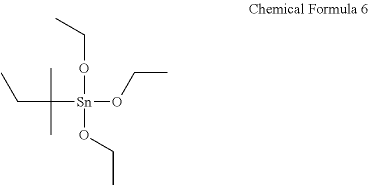

### Synthesis Example 3

10 g of dibutyltin dichloride was dissolved 30 mL of ether, 70 mL of a 1 molarity (M) sodium hydroxide (NaOH) aqueous solution was added thereto and then, stirred for 1 hour. After the stirring, a solid produced therein was filtered, three times washed with 25 mL of deionized water, and dried at 100° C. under a reduced pressure to obtain an organometallic compound represented by Chemical Formula 7 and having a weight average molecular weight of 1,500.

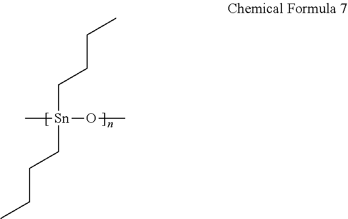

### Preparation of Semiconductor Photoresist Compositions

### Examples 1 to 21 and Comparative Examples 1 to 3

The organometallic compounds represented by Chemical Formula 5 to Chemical Formula 7 obtained in Synthesis Examples 1 to 3 were each dissolved in propylene glycol methyl ether acetate (PGMEA) at a concentration of 3 wt %, and alcohol compounds A1 to A4 substituted with at least one halogen and alcohol compounds B1 and B2 unsubstituted with halogen were added in the weight ratios shown in Table 1 and dissolved, and then filtered through a 0.1 micrometer (μm) PTFE (polytetrafluoroethylene) syringe filter to prepare semiconductor photoresist compositions according to Examples 1 to 21 and Comparative Examples 1 to 3.

TABLE 1

| | | Halogen- | Halogen- |
|---|---|---|---|
| | | substituted | unsubstituted |
| | Organometallic | alcohol | alcohol |
| | compound | compound | compound |
| | (wt %) | (wt %) | (wt %) |
| Comparative | Chemical Formula 5 | — | |
| Example 1 | (3.0) | | |
| Comparative | Chemical Formula 5 | — | B1 |
| Example 2 | (2.5) | | 0.5 |
| Comparative | Chemical Formula 5 | A1 | — |
| Example 3 | (2.5) | (0.5) | |
| Example 1 | Chemical Formula5 | A1 | B1 |
| | (2.5) | (0.5) | (0.2) |
| Example 2 | Chemical Formula 5 | A1 | B2 |
| | (2.3) | (0.5) | (0.2) |
| Example 3 | Chemical Formula 5 | A2 | B1 |
| | (2.3) | (0.5) | (0.2) |
| Example 4 | Chemical Formula 5 | A2 | B2 |
| | (2.3) | (0.5) | (0.2) |
| Example 5 | Chemical Formula 5 | A3 | B1 |
| | (2.3) | (0.35) | (0.35 |
| Example 6 | Chemical Formula 5 | A3 | B2 |
| | (2.3) | (0.2) | (0.5) |
| Example 7 | Chemical Formula 5 | A4 | B1 |
| | (2.3) | (0.5) | (0.2) |
| Example 8 | Chemical Formula 5 | A4 | B2 |
| | (2.3) | (0.5) | (0.2) |
| Example 9 | Chemical Formula 5 | A1 | B2 |
| | (2.3) | (0.5) | (0.2) |
| Example 10 | Chemical Formula 5 | A1 | B2 |
| | (2.3) | (0.35 | (0.35) |
| Example 11 | Chemical Formula 5 | A1 | B2 |
| | (2.3) | (0.2) | (0.5) |
| Example 12 | Chemical Formula 5 | A1 | B2 |
| | (2.3) | (0.05) | (0.65) |
| Example 13 | Chemical Formula 5 | A1 | B2 |
| | (2.25) | (0.5) | (0.25) |
| Example 14 | Chemical Formula 5 | A1 | B2 |
| | (2.2) | (0.5) | (0.3) |
| Example 15 | Chemical Formula 5 | A1 | B2 |
| | (2.15) | (0.5) | (0.35) |
| Example 16 | Chemical Formula 6 | A1 | B1 |
| | (2.5) | (0.4) | (0.1) |
| Example 17 | Chemical Formula 6 | A1 | B2 |
| | (2.5) | (0.4) | (0.1) |
| Example 18 | Chemical Formula 6 | A2 | B1 |
| | (2.5) | (0.4) | (0.1) |
| Example 19 | Chemical Formula 7 | A2 | B2 |
| | (2.5) | (0.4) | (0.1) |
| Example 20 | Chemical Formula 7 | A3 | B1 |
| | (2.5) | (0.25) | (0.25) |
| Example 21 | Chemical Formula 7 | A3 | B2 |
| | (2.5) | (0.1) | (0.4) |

### Halogen-Substituted Alcohol Compound

A1: 2-iodoethanol, A2: 4-iodophenol,
A3: 2-fluoroethanol, A4: 2-fluorophenol

### [Halogen-Unsubstituted Alcohol Compound]

B1: Propanol, B2: Pinacol

### Evaluation 1: Evaluation of Surface Roughness (Rq)

Each of the photoresist compositions was spin-coated on a wafer at 1500 rpm for 60 seconds and baked at 110° C. for 60 seconds to form a thin film, which was taken an image of with an atomic force microscopy (AFM) and/or the like, and the image was used to measure surface roughness of the thin film according to the following criteria by using a software (optical profiler), and the results are shown in Table 2.

Evaluation criteria for surface roughness (Rq value)
∘: less than or equal to 0.4
Δ: greater than 0.4 and less than or equal to 0.7
X: greater than 0.7

### Evaluation 2: Evaluation of Sensitivity and LER Characteristics

Each of the photoresist compositions according to the Examples and the Comparative Examples was spin-coated for 30 seconds at 1500 rpm, respectively, on a 200 millimeter (mm) circular silicon wafer whose surface was deposited with HMDS, and baked at 110° C. for 60 seconds. After application, it was baked (post-apply baked, PAB) and then left at room temperature (23±2° C.) for 30 seconds.

Then, a linear array with a width of 50 nanometer (nm) was projected onto the wafer coated with the photoresist composition using EUV light (Lawrence Berkeley National Laboratory Micro Exposure Tool, MET). Here, pad exposure time was adjusted to ensure that the EUV light in an increased dose was applied to each pad.

Then, the resist and the substrate were baked at 160° C. for 120 seconds on a hot plate after the exposure. The baked film was developed in a PGMEA solvent to form a negative tone image. Finally, the obtained film was baked again at 150° C. for 2 minutes on the hot plate, completing the process.

CD-SEM was used to measure resist line widths to exposed dose (energy) changes. The sensitivity to the exposure amount was confirmed from the resist line width values formed differently according to each exposure dose, and the sensitivity and LER were evaluated according to the following criteria, and the results are shown in Table 2.

### Evaluation Criteria for Sensitivity

A: less than 33 millijoule per square centimeter (mJ/cm²)
B: greater than or equal to 33 mJ/cm² and less than 36 mJ/cm²
C: greater than or equal to 36 mJ/cm² and less than 39 mJ/cm²
   D: greater than or equal to 40 mJ/cm²

### Evaluation Criteria for LER

⊚: less than 3 nm
∘: greater than or equal to 3 nm and less than 4 nm
Δ: greater than or equal to 4 nm and less than 5 nm
X: greater than or equal to 5 nm

TABLE 2

| | Surface | | |
|---|---|---|---|
| | roughness | Sensitivity | LER |
| Comparative | X | D | Δ |
| Example 1 | | | |
| Comparative | Δ | D | X |
| Example 2 | | | |
| Comparative | ◯ | D | Δ |
| Example 3 | | | |
| Example 1 | Δ | C | ◯ |
| Example 2 | ◯ | B | ⊚ |
| Example 3 | X | C | ◯ |
| Example 4 | ◯ | A | ⊚ |
| Example 5 | ◯ | B | ◯ |
| Example 6 | ◯ | A | ⊚ |
| Example 7 | ◯ | C | ◯ |
| Example 8 | ◯ | A | ⊚ |
| Example 9 | ◯ | B | ◯ |
| Example 10 | ◯ | B | ◯ |
| Example 11 | Δ | B | Δ |
| Example 12 | ◯ | A | ◯ |
| Example 13 | X | C | ◯ |
| Example 14 | Δ | C | ◯ |
| Example 15 | ◯ | D | ◯ |
| Example 16 | Δ | B | ⊚ |
| Example 17 | ◯ | B | Δ |
| Example 18 | ◯ | B | ⊚ |
| Example 19 | ◯ | A | Δ |
| Example 20 | X | B | Δ |
| Example 21 | X | C | ◯ |

From the results in Table 2, the semiconductor photoresist compositions according to Examples 1 to 21 exhibited enhanced (e.g., superior) sensitivity and LER characteristics compared to Comparative Examples 1 to 3.

As utilized herein, the terms “and/or” and “or” may include any and all combinations of one or more of the associated listed items. The “/” utilized herein may be interpreted as “and” or as “or” depending on the situation. In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, and/or the like, may indicate only a, only b, only c, both (e.g., simultaneously) a and b, both (e.g., simultaneously) a and c, both (e.g., simultaneously) b and c, all of a, b, and c, or variations thereof.

It will be further understood that the terms “comprise(s)/comprising”, “include(s)/including,” or “have/has/having,” when utilized in the present disclosure, specify the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the singular forms “a,” “an,” and “the” are intended to include the plural forms as well, unless the context clearly indicates otherwise. Further, the utilization of “may” when describing embodiments of the present disclosure refers to “one or more embodiments of the present disclosure”.

In the context of the present disclosure and unless otherwise defined, the terms “use,” “using,” and “used” may be considered synonymous with the terms “utilize,” “utilizing,” and “utilized,” respectively.

As utilized herein, the term “about,” or similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and refers to within an acceptable range of deviation for the particular value as determined by one of ordinary skill in the art, considering the measurement in question and the error associated with measurement of the particular quantity (i.e., the limitations of the measurement system). For example, “about” may refer to within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art would appreciate, in view of the present disclosure in its entirety, that each suitable feature of the embodiments of the present disclosure may be combined or combined with each other, partially or entirely, and may be technically interlocked and operated in suitable ways, and each embodiment may be implemented independently of each other or in conjunction with each other in any suitable manner unless otherwise stated or implied.

A pattern forming device, a semiconductor forming device and/or any other relevant devices or components according to embodiments of the present invention described herein may be implemented utilizing any suitable hardware, firmware (e.g., an application-specific integrated circuit), software, or a combination of software, firmware, and hardware. For example, the components of the device may be formed on one integrated circuit (IC) chip or on separate IC chips. Further, the components of the device may be implemented on a flexible printed circuit film, a tape carrier package (TCP), a printed circuit board (PCB), or formed on one substrate. Further, the components of the device may be a process or thread, running on one or more processors, in one or more computing devices, executing computer program instructions and interacting with other system components for performing the functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of computing devices may be combined or integrated into a single computing device, or the functionality of a particular computing device may be distributed across one or more other computing devices without departing from the scope of the present disclosure.

Hereinbefore, the certain embodiments have been described and illustrated, however, it is apparent to a person with ordinary skill in the art that the present disclosure is not limited to the embodiment as described, and may be modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure and equivalents thereof.

### REFERENCE NUMERALS

| | |
|---|---|
| 100: substrate | 102: thin film |
| 104: resist underlayer | 106: photoresist film |
| 106a: unexposed region | 106b: exposed region |
| 108: photoresist pattern | 112: organic film pattern |
| 110: patterned mask | 114: thin film pattern |

What is claimed is:

1. A semiconductor photoresist composition, comprising
an organometallic compound;
an alcohol compound, the alcohol compound being substituted with at least one halogen;
a halogen-unsubstituted alcohol compound; and
a solvent.

2. The semiconductor photoresist composition as claimed in claim 1, wherein
the alcohol compound is represented by Chemical Formula 1: 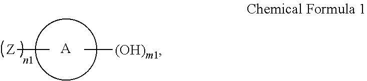
and
wherein, in Chemical Formula 1,
Z is a halogen,
A is at least one selected from among a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkane, a substituted or unsubstituted C3 to C20 cycloalkene, and a substituted or unsubstituted C6 to C20 aromatic ring,
n1 and m1 are each independently an integer of greater than or equal to 1, and
n1+m1 is an integer less than or equal to a valence of A.

3. The semiconductor photoresist composition as claimed in claim 2, wherein
the alcohol compound is represented by any one selected from among Chemical Formula 1-1 to Chemical Formula 1-4: 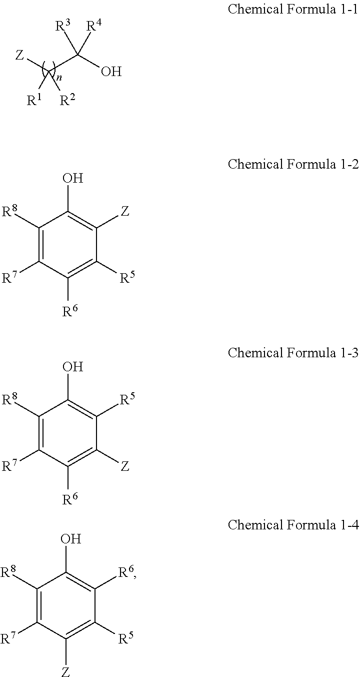
and
wherein, in Chemical Formula 1-1 to Chemical Formula 1-4,
Z is a halogen,
R¹ to R⁸ are each independently hydrogen, a halogen, a hydroxy group, an amino group, a nitro group, a substituted or unsubstituted C1 to C30 amine group, a substituted or unsubstituted C1 to C10 alkyl group, or a substituted or unsubstituted C6 to C20 aryl group, and
n is one of integers from 1 to 10.

4. The semiconductor photoresist composition as claimed in claim 1, wherein
the alcohol compound is any one selected from among compounds in Group 1:

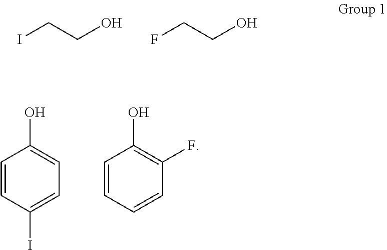

5. The semiconductor photoresist composition as claimed in claim 1, wherein
the halogen-unsubstituted alcohol compound is represented by Chemical Formula 2: 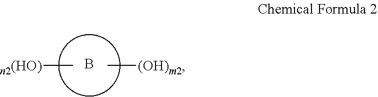
and
wherein, in Chemical Formula 2,
B is at least one selected from among a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkane, a substituted or unsubstituted C3 to C20 cycloalkene, and a substituted or unsubstituted C6 to C20 aromatic ring,
n2 and m2 are each independently an integer of greater than or equal to 0,
n2+m2 is an integer of greater than or equal to 1 and less than or equal to a valence of B, and
substituents in a case of “substituted” exclude a halogen.

6. The semiconductor photoresist composition as claimed in claim 5, wherein
the halogen-unsubstituted alcohol compound is represented by Chemical Formula 2-1: 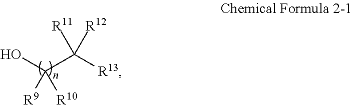
and
wherein, in Chemical Formula 2-1,
R⁹ to R¹³ are each independently hydrogen, a hydroxy group, an amino group, a nitro group, a substituted or unsubstituted C1 to C30 amine group, a substituted or unsubstituted C1 to C10 alkyl group, or a substituted or unsubstituted C6 to C20 aryl group, and
n is an integer from 1 to 9.

7. The semiconductor photoresist composition as claimed in claim 1, wherein
the halogen-unsubstituted alcohol compound is any one selected from among compounds in Group 2:

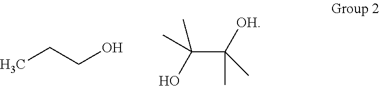

8. The semiconductor photoresist composition as claimed in claim 1, wherein
the alcohol compound and the halogen-unsubstituted alcohol compound are in a weight ratio of about 10:1 to about 1:15.

9. The semiconductor photoresist composition as claimed in claim 1, wherein
each of the alcohol compound and the halogen-unsubstituted alcohol compound are in an amount of about 0.01 wt % to about 20 wt % based on 100 wt % of a total weight of the semiconductor photoresist composition.

10. The semiconductor photoresist composition as claimed in claim 1, wherein
the organometallic compound is in an amount of about 0.5 wt % to about 30 wt % based on 100 wt % of a total weight of the semiconductor photoresist composition.

11. The semiconductor photoresist composition as claimed in claim 1, wherein
the semiconductor photoresist composition further comprises an additive comprising a surfactant, a crosslinking agent, a leveling agent, an organic acid, a quencher, or a combination thereof.

12. The semiconductor photoresist composition as claimed in claim 1, wherein
the organometallic compound comprises at least one selected from among an organic oxy group and an organic carbonyloxy group.

13. The semiconductor photoresist composition as claimed in claim 1, wherein
the organometallic compound is represented by Chemical Formula 3: 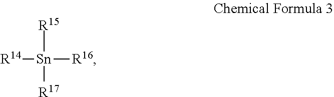
and
wherein, in Chemical Formula 3,
R¹⁴ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R¹⁵ to R¹⁷ are each independently
a substituted or unsubstituted C1 to C20 alkyl group,
a substituted or unsubstituted C3 to C20 cycloalkyl group,
a substituted or unsubstituted C2 to C20 alkenyl group,
a substituted or unsubstituted C2 to C20 alkynyl group,
a substituted or unsubstituted C6 to C30 aryl group,
a substituted or unsubstituted C7 to C30 arylalkyl group,
an alkoxy or aryloxy group —OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
a carboxyl group —O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
an alkylamido or dialkylamido group —NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
an amidato group —NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
an amidinato group —NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
an alkylthio or arylthio group —SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, or
a thiocarboxyl group —S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
at least one selected from among R¹⁵ to R¹⁷ is selected from among the alkoxy or aryloxy group —OR^{b}, the carboxyl group —O(CO)R^{c}, the alkylamido or dialkylamido group —NR^{d}R^{e}, the amidato group —NR^{f}(COR^{g}), the amidinato group —NR^{h}C(NRⁱ)R^{j}, the alkylthio or arylthio group —SR^{k}, and the thiocarboxyl group —S(CO)R^{l}.

14. The semiconductor photoresist composition as claimed in claim 13, wherein
at least one selected from among R¹⁵ to R¹⁷ is selected from among the alkoxy or aryloxy group —OR^{b}, and the carboxyl group —O(CO)R^{c}.

15. The semiconductor photoresist composition as claimed in claim 14, wherein
R¹⁴ is a substituted or unsubstituted C1 to C8 alkyl group, a substituted or unsubstituted C3 to C8 cycloalkyl group, a substituted or unsubstituted C2 to C8 aliphatic unsaturated organic group comprising one or more double bonds or triple bonds, a substituted or unsubstituted C6 to C20 aryl group, a substituted or unsubstituted C4 to C20 heteroaryl group, a carbonyl group, an ethoxy group, a propoxy group, or a combination thereof,
R^{b} is a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} is hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

16. The semiconductor photoresist composition as claimed in claim 1, wherein
the organometallic compound is represented by Chemical Formula 4 or Chemical Formula 5: 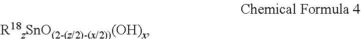
wherein, in Chemical Formula 4,
R¹⁸ is a C1 to C31 hydrocarbyl group,
0<z≤2, and 0
0<(z+x)≤4; 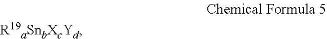
wherein, in Chemical Formula 5,
R¹⁹ is a substituted or unsubstituted C1 to C20 alkyl group, a substituted or unsubstituted C3 to C20 cycloalkyl group, a substituted or unsubstituted C2 to C20 aliphatic unsaturated organic group comprising one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X is sulfur(S), selenium (Se), or tellurium (Te),
Y is —OR^{m} or —OC(═O)Rⁿ, and
wherein R^{m} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d are each independently an integer of 1 to 20.

17. A method comprising
forming an etching-objective layer on a substrate;
coating the semiconductor photoresist composition as claimed in claim 1 on the etching-objective layer to form a photoresist film;
patterning the photoresist film to form a photoresist pattern; and
etching the etching-objective layer utilizing the photoresist pattern as an etching mask,
wherein the method is a method of forming patterns.

18. The method as claimed in claim 17,
wherein the alcohol compound is 2-iodoethanol, 4-iodophenol, 2-fluoroethanol, 2-fluorophenol, or a combination thereof.

19. The method as claimed in claim 17,
wherein the halogen-unsubstituted alcohol compound is propanol, pinacol, or a combination thereof.

20. The method as claimed in claim 18,
wherein the halogen-unsubstituted alcohol compound is propanol, pinacol, or a combination thereof.
